(19) United States
(12) Patent Application Publication
(10) Pub. No.: US 2009/0014801 A1
(43) Pub. Date: Jan. 15, 2009

(54) DECOUPLING CAPACITOR CIRCUIT AND LAYOUT FOR LEAKAGE CURRENT REDUCTION AND ESD PROTECTION IMPROVEMENT

(75) Inventors: Wang-Jin Chen, Kaohsiung County (TW); Chia-Nan Hong, Hsinchu City (TW)

Correspondence Address: J C PATENTS, INC., 4 VENTURE, SUITE 250, IRVINE, CA, 92618, US

(73) Assignee: FARADAY TECHNOLOGY CORP., Hsinchu (TW)

(21) Appl. No.: 11/775,584

(22) Filed: Jul. 10, 2007

(51) Int. Cl. H01L 23/62

(52) U.S. Cl. 257/357; 257/E23.001

(57) ABSTRACT

In order to reduce the leakage current and increase the ESD protection performance, several MOS capacitors are serially connected. The E field between the gate and the source/drain of the MOS transistor is lowered and so is the gate leakage current. Besides, because the ESD voltage is distributed on the gates of the MOS capacitors, the MOS capacitors have good ESD protection performance.

### BACKGROUND OF THE INVENTION

1. Field of Invention

The present invention relates to a decoupling capacitor circuit and layout for reducing gate leakage current and improving ESD protection.

2. Description of Related Art

In integrated circuits (IC), decoupling capacitors are very important for reducing power/ground noise to make sure the power supply quality when the ICs are in operation. Usually, decoupling capacitors are formed by MOS transistors whose sources and drains are coupled together. FIG. 1 shows a MOS capacitor and the layout thereof.

Because of the improvements on fabrication processes, the gate oxide of the MOS transistor is thin. For example, the thickness thereof may be tens of Å. The thinner the gate oxide, the higher the E (Electronic) field between the gate and the source/drain. It is known that the E field between the gate and the source/drain is proportional to the voltage drop between the gate and the source/drain. In FIG. 1, the voltage drop between the gate and the source/drain is substantially the same as VCC. Therefore, the gate leakage current is not neglectful.

For example, a memory with 6000 um×2 um decoupling capacitor may have a gate leakage current of 91 uA in 90 nm process. In low power application, the gate leakage current may be higher.

A chip having a circuit area of 6000 um (height) and 6000 um (width), whose 30% area is used as decoupling capacitors, may have a high gate leakage current of 81 mA in 90 nm process.

Therefore, it is preferred to have a new decoupling capacitor structure which reduces the leakage current and increases the ESD protection.

### SUMMARY OF THE INVENTION

One of the aspects of the invention is to provide a new decoupling capacitor structure which reduces the leakage current and increases the ESD protection.

The invention provides a decoupling capacitor structure, comprising: a substrate of first conductive type; a deep buried well of second conductive type in the substrate; a first well of first conductive type over the deep buried well of second conductive type in the substrate, wherein the substrate, the deep buried well and the first well form a triple well structure; a second well of second conductive type in the substrate; a first MOS transistor in the substrate, the first MOS transistor having a first terminal, a second terminal, a control terminal and a bulk terminal; and a second MOS transistor in the substrate, the second MOS transistor having a first terminal, a second terminal, a control terminal and a bulk terminal; wherein the first terminal, the second terminal, the bulk terminal of the first MOS transistor are coupled to a first reference voltage; the control terminal of the first MOS transistor is coupled to the control terminal of the second MOS transistor; and the first terminal, the second terminal, the bulk terminal of the second MOS transistor are coupled to a second reference voltage.

Further, the invention also provides a decoupling capacitor structure, comprising: a substrate of first conductive type; a first well of first conductive type in the substrate; a second well of second conductive type in the substrate; a first MOS transistor in the substrate, the first MOS transistor having a first terminal, a second terminal, a control terminal and a bulk terminal; and a second MOS transistor in the substrate, the second MOS transistor having a first terminal, a second terminal, a control terminal and a bulk terminal; wherein the control terminal of the first MOS transistor is coupled to a first reference voltage; the first terminal, the second terminal and the bulk terminal of the first MOS transistor is coupled to the control terminal of the second MOS transistor; and the first terminal, the second terminal, the bulk terminal of the second MOS transistor are coupled to a second reference voltage.

Still further, the invention provides a decoupling capacitor structure, comprising: a substrate of first conductive type; a first deep buried well of second conductive type in the substrate; a first well of first conductive type over the first deep buried well of second conductive type in the substrate, wherein the substrate, the first deep buried well and the first well form a first triple well structure; a second deep buried well of second conductive type in the substrate; a second well of first conductive type over the second deep buried well of second conductive type in the substrate, wherein the substrate, the second deep buried well and the second well form a second triple well structure; a first MOS transistor in the substrate, the first MOS transistor having a first terminal, a second terminal, a control terminal and a bulk terminal; and a second MOS transistor in the substrate, the second MOS transistor having a first terminal, a second terminal, a control terminal and a bulk terminal; wherein the first terminal, the second terminal, the bulk terminal of the first MOS transistor are coupled to the control terminal of the second MOS transistor; the control terminal of the first MOS transistor is coupled to a first reference voltage; and the first terminal, the second terminal, the bulk terminal of the second MOS transistor are coupled to a second reference voltage.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 shows a MOS capacitor and the layout thereof.

FIG. 2 is a layout diagram of serial PMOS and NMOS capacitors and the equivalent circuit thereof according to an embodiment of the invention.

FIG. 3 is a layout diagram of serial PMOS capacitors and the equivalent circuit thereof according to the embodiment of the invention.

FIG. 4 is a layout diagram of serial NMOS capacitors and the equivalent circuit thereof according to the embodiment of the invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

In order to reduce the leakage current and increase the ESD protection performance, in an embodiment of the invention, two or more MOS capacitors are serially connected. The E field between the gate and the source/drain of the MOS transistor is lowered and so is the gate leakage current. Besides, because the ESD voltage is distributed on the gates of the MOS capacitors, each of the MOS capacitors has good ESD protection performance.

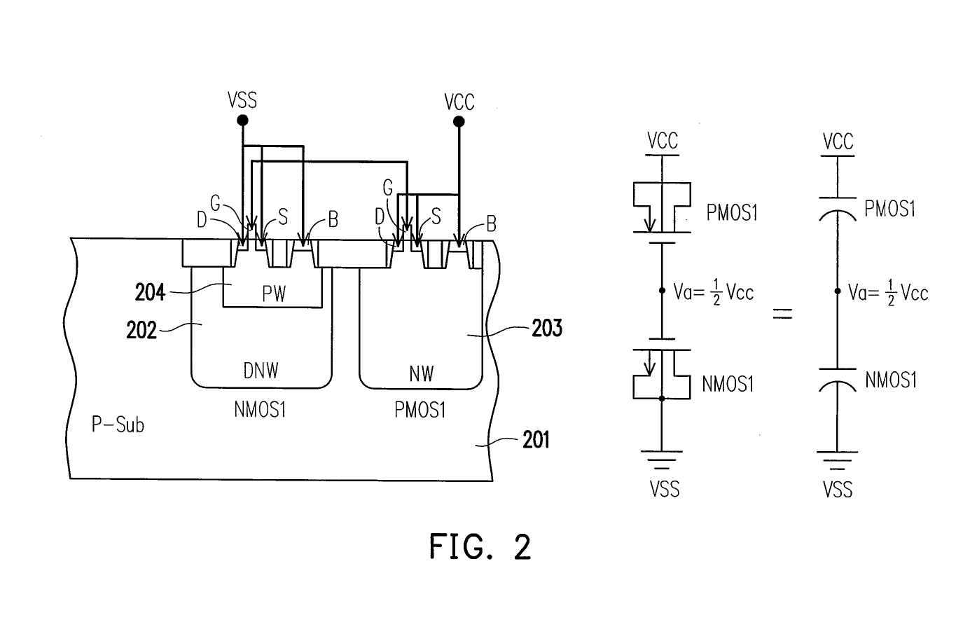

FIG. 2 is a layout diagram of serial PMOS and NMOS capacitors and the equivalent circuit thereof according to an embodiment of the invention. Now please refer to FIG. 2, the layout structure of the serial PMOS and NMOS capacitors includes a P-type substrate (P-sub) 201, a deep N-type well (DNW) 202, a N-type well (NW) 203, a P-type well (PW) 204, gate terminals (G), bulk terminals (B), source terminals (S) and drain terminals (D). A P-type transistor PMOS1 and an N-type transistor NMOS1 are both formed in the P-sub 201. Further, the transistor PMSO1 is formed in the PW 204 and the transistor NMOS1 is formed in the NW 203.

More specially, the DNW 202 with high energy implant is formed in the P-sub 201 and further PW 204 is formed in the DNW 202. The P-sub 201, the DNW 202 and the PW 204 together form a triple well structure. The NW 203 is formed in the P-sub 201.

The bulk terminal, the source terminal and the drain terminal of the transistor PMOS1 are coupled to a power supply VCC. The gate terminal of the transistor PMOS1 is coupled to the gate terminal of the transistor NMOS1. The bulk terminal, the source terminal and the drain terminal of the transistor NMOS1 are coupled to a ground terminal VSS.

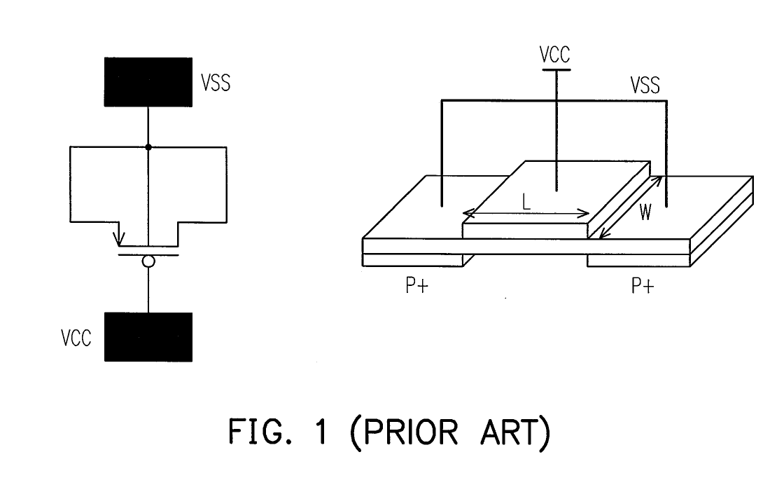

Because of the serial layout structure of FIG. 2, the voltage drop between the gate and the source/drain in the transistor of FIG. 2 is smaller than that in the prior art of FIG. 1. Further, if the transistor PMOS1 has substantially the same capacitance as the transistor NMOS1, then the voltage drop between the gate and the source/drain of the transistor PMOS1 is, for example, ½ VCC, the same as the voltage drop between the gate and the source/drain of the transistor NMOS1, which is lower than the voltage drop between the gate and the source/drain of the prior circuit.

Therefore, the E field in the transistor PMSO1/NMOS1 is lowered compared to the E field in the prior circuit. So, the gate leakage current in the transistor PMSO1/NMOS1 of the embodiment is also lowered.

Still further, the ESD voltage originally on the gate of the transistor PMOS1 may be distributed onto the gates of the transistors PMOS1 and NMOS1. This means, the ESD protection performance of the transistors PMOS1 and NMOS1 is increased. Besides, in the layout structure of FIG. 2, the DNW 202 is optional.

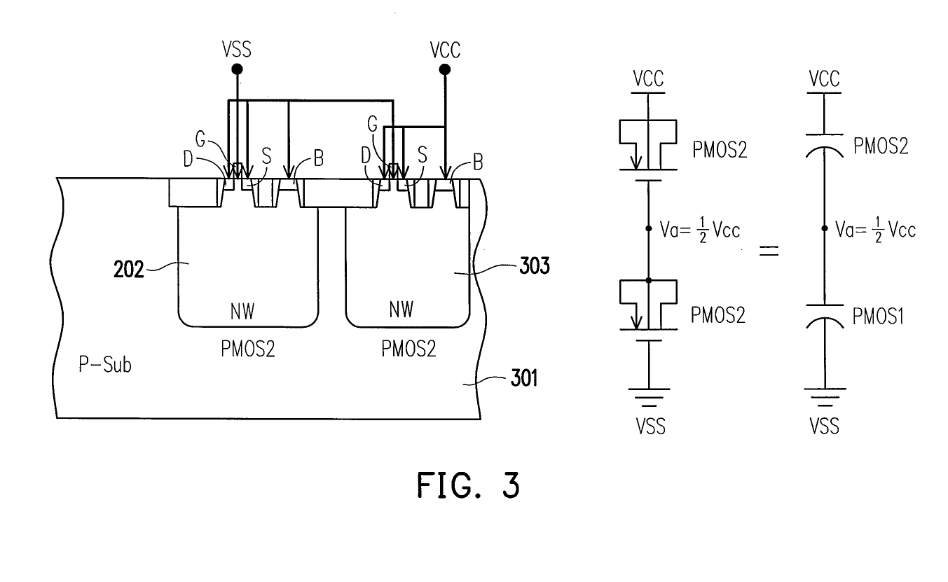

FIG. 3 is a layout diagram of serial PMOS capacitors and the equivalent circuit thereof according to the embodiment of the invention. Now please refer to FIG. 3, the layout structure of the serial PMOS capacitors includes a P-type substrate (P-sub) 301, N-type wells (NW) 302 and 303, gate terminals (G), bulk terminals (B), source terminals (S) and drain terminals (D). P-type transistors PMOS1 PMOS2 are both formed in the P-sub 301. Further, the transistor PMOS1 is formed in the NW 302 and the transistor PMOS2 is formed in the NW 303.

More specially, the NW 302 is formed in the P-sub 301 and so is the NW 303.

The bulk terminal, the source terminal and the drain terminal of the transistor PMOS2 are coupled to a power supply VCC. The gate terminal of the transistor PMOS2 is coupled to the gate terminal of the transistor PMOS1. The bulk terminal, the source terminal and the drain terminal of the transistor PMOS1 are coupled to a ground terminal VSS.

Similarly, the voltage drop between the gate and the source/drain of the transistor PMOS1 is, for example, ½ VCC, the same as the voltage drop between the gate and the source/drain of the transistor PMOS2, which is lower than the voltage drop between the gate and the source/drain of the prior circuit. Therefore, the E field in the transistor PMSO1/PMOS2 is lowered compared to the E field in the prior circuit. So, the gate leakage current in the transistor PMOS1/PMOS2 of the embodiment is also lowered.

Still further, the ESD voltage originally on the gate of the transistor PMOS1 may be distributed onto the gates of the transistors PMOS1 and PMOS2. This means, the ESD protection performance of the transistors PMOS1 and PMOS2 is increased.

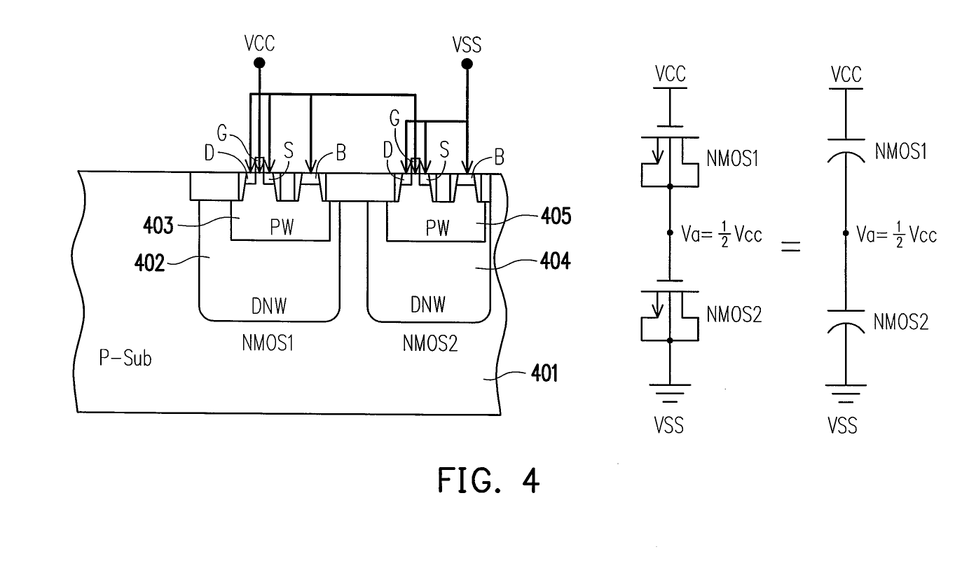

FIG. 4 is a layout diagram of serial NMOS capacitors and the equivalent circuit thereof according to the embodiment of the invention. Now please refer to FIG. 4, the layout structure of the serial NMOS capacitors includes a P-type substrate (P-sub) 401, deep N-type wells (DNW) 402 and 404, P-type wells (PW) 403 and 405, gate terminals (G), bulk terminals (B), source terminals (S) and drain terminals (D). N-type transistors NMOS1 and NMOS2 are both formed in the P-sub 401. Further, the transistor NMOS1 is formed in the PW 403 and the transistor PMOS2 is formed in the PW 405.

More specially, the DNW 402 with high energy implant is formed in the P-sub 401 and further the PW 403 is formed in the DNW 402. The P-sub 401, the DNW 202 and the PW 204 together form a triple well structure. The DNW 404 with high energy implant is also formed in the P-sub 401 and further the PW 405 is formed in the DNW 404. The P-sub 401, the DNW 404 and the PW 405 together form a triple well structure.

The bulk terminal, the source terminal and the drain terminal of the transistor NMOS2 are coupled to a power supply VCC. The gate terminal of the transistor NMOS2 is coupled to the gate terminal of the transistor NMOS1. The bulk terminal, the source terminal and the drain terminal of the transistor NMOS1 are coupled to a ground terminal VSS.

Similarly, the voltage drop between the gate and the source/drain of the transistor NMOS1 is, for example, ½ VCC, the same as the voltage drop between the gate and the source/drain of the transistor NMOS2, which is lower than the voltage drop between the gate and the source/drain of the prior circuit. Therefore, the E field in the transistor NMOS1/NMOS2 is lowered compared to the E field in the prior circuit. So, the gate leakage current in the transistor NMOS1/NMOS2 of the embodiment is also lowered.

Still further, the ESD voltage originally on the gate of the transistor NMOS1 may be distributed onto the gates of the transistors NMOS1 and NMOS2. This means, the ESD protection performance of the transistors NMOS1 and NMOS2 is increased.

In FIGS. 2˜4, although the substrate is of P-type, however, the substrate may be of N-type.

Accordingly, in the simulation result of the embodiment, the gate leakage current may be reduced about 90%. Furthermore, the leakage current is inverse proportion to the serial number of MOS capacitors.

Besides, the ESD performance is doubly improved in case of two serial MOS capacitors, ideally. The voltage drop between the gate and the drain/source is equal to the half of the power supply voltage. Therefore, the embodiment may improve the ESD performance. Still further, the ESD performance is proportional to the serial number of the MOS capacitors.

This embodiment may be applied in decoupling capacitor of ASIC chip for 90 nm, 60 nm etc. Besides, the invention may be applied in analog IPs or digital IPs for 90 nm, 60 nm etc.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A decoupling capacitor structure, comprising:
a substrate of first conductive type;
a deep buried well of second conductive type in the substrate;
a first well of first conductive type over the deep buried well of second conductive type in the substrate, wherein the substrate, the deep buried well and the first well form a triple well structure;
a second well of second conductive type in the substrate;
a first MOS transistor in the substrate, the first MOS transistor having a first terminal, a second terminal, a control terminal and a bulk terminal; and
a second MOS transistor in the substrate, the second MOS transistor having a first terminal, a second terminal, a control terminal and a bulk terminal;
wherein the first terminal, the second terminal, the bulk terminal of the first MOS transistor are coupled to a first reference voltage; the control terminal of the first MOS transistor is coupled to the control terminal of the second MOS transistor; and the first terminal, the second terminal, the bulk terminal of the second MOS transistor are coupled to a second reference voltage.

2. The decoupling capacitor structure of claim 1, wherein the first reference voltage is a common ground voltage.

3. The decoupling capacitor structure of claim 1, wherein the second reference voltage is a power supply voltage.

4. The decoupling capacitor structure of claim 1, wherein the first conductive type is N-type and the second conductive type is P-type.

5. The decoupling capacitor structure of claim 1, wherein the first conductive type is P-type and the second conductive type is N-type.

6. A decoupling capacitor structure, comprising:
a substrate of first conductive type;
a first well of first conductive type in the substrate;
a second well of second conductive type in the substrate;
a first MOS transistor in the substrate, the first MOS transistor having a first terminal, a second terminal, a control terminal and a bulk terminal; and
a second MOS transistor in the substrate, the second MOS transistor having a first terminal, a second terminal, a control terminal and a bulk terminal;
wherein the control terminal of the first MOS transistor is coupled to a first reference voltage; the first terminal, the second terminal and the bulk terminal of the first MOS transistor is coupled to the control terminal of the second MOS transistor; and the first terminal, the second terminal, the bulk terminal of the second MOS transistor are coupled to a second reference voltage.

7. The decoupling capacitor structure of claim 6, wherein the first reference voltage is a common ground voltage.

8. The decoupling capacitor structure of claim 6, wherein the second reference voltage is a power supply voltage.

9. The decoupling capacitor structure of claim 6, wherein the first conductive type is N-type and the second conductive type is P-type.

10. The decoupling capacitor structure of claim 6, wherein the first conductive type is P-type and the second conductive type is N-type.

11. A decoupling capacitor structure, comprising:
a substrate of first conductive type;
a first deep buried well of second conductive type in the substrate;
a first well of first conductive type over the first deep buried well of second conductive type in the substrate, wherein the substrate, the first deep buried well and the first well form a first triple well structure;
a second deep buried well of second conductive type in the substrate;
a second well of first conductive type over the second deep buried well of second conductive type in the substrate, wherein the substrate, the second deep buried well and the second well form a second triple well structure;
a first MOS transistor in the substrate, the first MOS transistor having a first terminal, a second terminal, a control terminal and a bulk terminal; and
a second MOS transistor in the substrate, the second MOS transistor having a first terminal, a second terminal, a control terminal and a bulk terminal;
wherein the first terminal, the second terminal, the bulk terminal of the first MOS transistor are coupled to the control terminal of the second MOS transistor; the control terminal of the first MOS transistor is coupled to a first reference voltage; and the first terminal, the second terminal, the bulk terminal of the second MOS transistor are coupled to a second reference voltage.

12. The decoupling capacitor structure of claim 11, wherein the first reference voltage is a power supply voltage.

13. The decoupling capacitor structure of claim 11, wherein the second reference voltage is a common ground voltage.

14. The decoupling capacitor structure of claim 11, wherein the first conductive type is N-type and the second conductive type is P-type.

15. The decoupling capacitor structure of claim 11, wherein the first conductive type is P-type and the second conductive type is N-type.
